(19) United States
(12) Patent Application Publication
(10) Pub. No.: US 2025/0386705 A1
(43) Pub. Date: Dec. 18, 2025

(54) DISPLAY DEVICE AND ELECTRONIC DEVICE INCLUDING DISPLAY DEVICE

(71) Applicant: Samsung Display Co., Ltd., Yongin-si (KR)

(72) Inventor: Sang Ho KIM, Yongin-si (KR)

(21) Appl. No.: 19/237,947

(22) Filed: Jun. 13, 2025

(30) Foreign Application Priority Data
Jun. 18, 2024 (KR) 10-2024-0078776
Jul. 23, 2024 (KR) 10-2024-0096821

(51) Int. Cl. H10K 59/50; G02B 27/00; G02B 27/01; H10K 59/80; H10K 102/00

(52) U.S. Cl. CPC H10K 59/50; G02B 27/0018; G02B 27/0172; H10K 59/879; H10K 59/8791; G02B 2027/012; G02B 2027/0132; H10K 2102/351

(57) ABSTRACT

A display device according to one or more embodiments of the present disclosure includes: a substrate; a display unit on the substrate, and including first to third sub-pixels configured to emit light of different colors; a first phase retardation unit on the display unit, and including first phase retardation plates respectively overlapping with the first to third sub-pixels and having different phase differences from each other; a first polarizing plate on the first phase retardation unit; a second phase retardation unit on the first polarizing plate, and including second phase retardation plates respectively overlapping with the first to third sub-pixels and having different phase differences from each other; and a polarizing element layer on the second phase retardation unit, and including a pancake lens.

### CROSS-REFERENCE TO RELATED APPLICATION

The present application claims priority to and the benefit of Korean Patent Application No. 10-2024-0078776, filed on Jun. 18, 2024, and Korean Patent Application No. 10-2024-0096821, filed on Jul. 23, 2024, in the Korean Intellectual Property Office, the entire disclosures of which are incorporated herein by reference.

### BACKGROUND

### 1. Field

Aspects of embodiments of the present disclosure relate to a display device and an electronic device including the display device.

### 2. Description of the Related Art

As information technology develops, importance of a display device, which is a connection medium between a user and information, is emerging. In response to this, a use of a display device such as a liquid crystal display device and an organic light emitting display device is increasing.

Recently, a head-mounted display (HMD) device is being developed. The HMD is a display device that implements virtual reality (VR) or augmented reality (AR) in which a user wears the HMD in a form of glasses or a helmet and a focus is formed at a distance close to eyes. A high-resolution panel is applied to the HMD, and thus a pixel that may be applied to the high-resolution panel is being required. The above information disclosed in this Background section is only for enhancement of understanding of the background of the invention and therefore it may contain information that does not form the prior art.

### SUMMARY

An aspect of the present disclosure is to provide a display device in which a ghost phenomenon for each wavelength is improved.

Aspects of the present disclosure are not limited to the aspects described above, and other technical aspects which are not described will be clearly understood by those skilled in the art from the following description.

According to some embodiments of the disclosure, there is provided a display device including: a substrate; a display unit on the substrate, and including first to third sub-pixels configured to emit light of different colors; a first phase retardation unit on the display unit, and including first phase retardation plates respectively overlapping with the first to third sub-pixels and having different phase differences from each other; a first polarizing plate on the first phase retardation unit; a second phase retardation unit on the first polarizing plate, and including second phase retardation plates respectively overlapping with the first to third sub-pixels and having different phase differences from each other; and a polarizing element layer on the second phase retardation unit, and including a pancake lens.

In some embodiments, each of the first and second phase retardation plates may have a phase difference corresponding to a wavelength of light emitted by a corresponding overlapping sub-pixel among the first to third sub-pixels.

In some embodiments, each of the first and second phase retardation plates may have thicknesses different from each other according to the wavelength of the light emitted by the corresponding overlapping sub-pixel among the first to third sub-pixels.

In some embodiments, a wavelength of the light emitted by the first sub-pixel may be longer than a wavelength of the light emitted by the second and third sub-pixels, and the wavelength of the light emitted by the second sub-pixel may be longer than the wavelength of the light emitted by the third sub-pixel.

In some embodiments, among the first and second phase retardation plates, phase retardation plates overlapping with the first sub-pixel may have a thickness greater than that of phase retardation plates overlapping with the second and third sub-pixels.

In some embodiments, among the first and second phase retardation plates, the phase retardation plates overlapping with the second sub-pixel may have a thickness greater than that of phase retardation plates overlapping with the third sub-pixel.

In some embodiments, each of the first and second phase retardation plates may be a ¼ phase retardation plate.

In some embodiments, the first phase retardation plates and the second phase retardation plates respectively overlapping with the first to third sub-pixels may overlap with each other, and the first phase retardation unit and the second phase retardation unit may have substantially the same structure.

In some embodiments, each of the first and second phase retardation plates may include liquid crystal molecules.

In some embodiments, the first phase retardation unit may further include a first light blocking pattern surrounding the first phase retardation plates, and the second phase retardation unit may further include a second light blocking pattern surrounding the second phase retardation plates.

In some embodiments, the polarizing element layer may overlap with the first to third sub-pixels.

In some embodiments, the polarizing element layer may include: a half mirror on the second phase retardation unit; a third phase retardation unit on the half mirror; a second polarizing plate on the third phase retardation unit; and at least one lens between the half mirror and the second polarizing plate.

In some embodiments, the polarizing element layer may include at least one first lens between the half mirror and the third phase retardation unit.

In some embodiments, the polarizing element layer may include a second lens on the second polarizing plate.

In some embodiments, the third phase retardation unit may have substantially the same structure as the first and second phase retardation units.

In some embodiments, the second polarizing plate may have substantially the same structure as the first polarizing plate.

In some embodiments, the polarizing element layer may further include a third polarizing plate on the second polarizing plate.

In some embodiments, the third polarizing plate may bean absorption-type polarizing plate.

In some embodiments, the first polarizing plate may be a wire grid polarizing plate.

In some embodiments, the display device may further include a micro lens array between the second phase retardation unit and the polarizing element layer.

According to some embodiments of the disclosure, there is provided an electronic device including: a processor to provide input image data; and a display device to display an image based on the input image data, and a display device including: a substrate; a display unit on the substrate, and including first to third sub-pixels configured to emit light of different colors; a first phase retardation unit on the display unit, and including first phase retardation plates respectively overlapping with the first to third sub-pixels and having different phase differences from each other; a first polarizing plate on the first phase retardation unit; a second phase retardation unit on the first polarizing plate, and including second phase retardation plates respectively overlapping with the first to third sub-pixels and having different phase differences from each other; and a polarizing element layer on the second phase retardation unit, and including a pancake lens.

In the display device, since the phase retardation plates having different thicknesses for each sub-pixel are provided on the display unit, a ghost phenomenon for each wavelength may be improved, thereby improving a luminance and a light emission efficiency of the display device.

An effect according to embodiments is not limited by the contents exemplified above, and more various effects are included in the present specification.

### BRIEF DESCRIPTION OF THE DRAWINGS

The above and other features of the present disclosure will become more apparent by describing in further detail embodiments thereof with reference to the accompanying drawings, in which:

FIG. 1 is a block diagram illustrating a display device according to some embodiments of the present disclosure;

FIG. 2 is a block diagram illustrating one of sub-pixels of FIG. 1 according to some embodiments of the present disclosure;

FIG. 3 is a circuit diagram illustrating the sub-pixel of FIG. 2 according to some embodiments of the present disclosure;

FIG. 4 is a plan view illustrating a display panel of FIG. 1 according to some embodiments of the present disclosure;

FIG. 5 is an exploded perspective view illustrating a portion of a display device according to some embodiments of the present disclosure;

FIG. 6 is a plan view illustrating one of the pixels of FIG. 5 according to some embodiments of the present disclosure;

FIG. 7 is a schematic cross-sectional view taken along the line I-I′ of FIG. 6 according to some embodiments of the present disclosure;

FIG. 8 is a schematic cross-sectional view according to some other embodiments of the present disclosure;

FIG. 9 is a schematic cross-sectional view according to still other embodiments of the present disclosure;

FIG. 10 is a block diagram illustrating some embodiments of a display system according to some embodiments of the present disclosure;

FIG. 11 is a perspective view illustrating an application example of the display system of FIG. 10 according to some embodiments of the present disclosure; and

FIG. 12 is a diagram illustrating a head-mounted display device worn by a user of FIG. 11 according to some embodiments of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

The electronic or electric devices and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

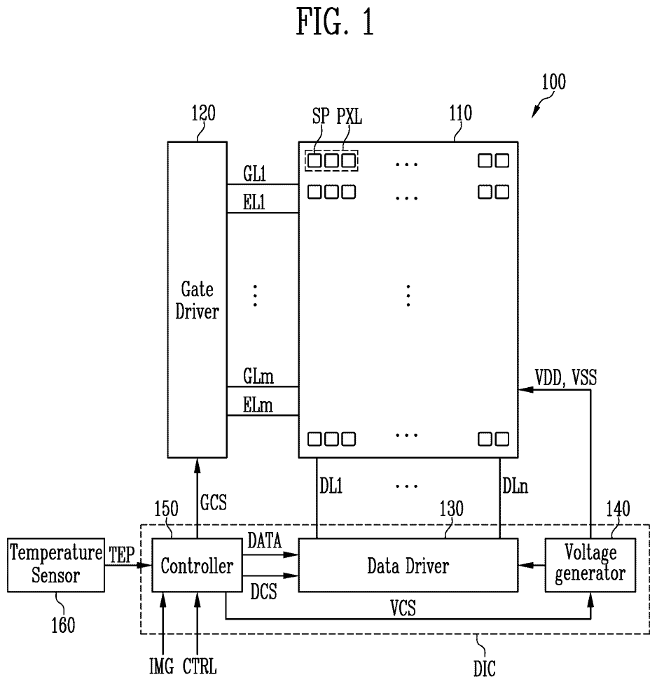

FIG. 1 is a block diagram illustrating a display device according to some embodiments of the present disclosure.

Referring to FIG. 1, the display device 100 may include a display panel 110, a gate driver 120, a data driver 130, a voltage generator 140, and a controller 150.

The display panel 110 includes sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light emitting element configured to generate light. Accordingly, each of the sub-pixels SP may generate light of a specific color, such as red, green, blue, cyan, magenta, or yellow. Two or more sub-pixels among the sub-pixels SP may configure (e.g., be included in) one pixel PXL. For example, as shown in FIG. 1, three sub-pixels may configure one pixel PXL. In other words, one pixel PXL may include two or more sub-pixels SP.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS. In some embodiments, the gate control signal GCS may include a start signal indicating a start of each frame, a horizontal synchronization signal for outputting the gate signals in synchronization with a timing at which data signals are applied, and the like.

In some embodiments, first to m-th emission control lines EL1 to ELm connected to the sub-pixels SP of the row direction may be provided. For example, the gate driver 120 may include an emission control driver configured to control the first to m-th emission control lines EL1 to ELm, and the emission control driver may operate under control of the controller 150.

The gate driver 120 may be disposed on one side of the display panel 110. However, embodiments are not limited thereto. For example, the gate driver 120 may be divided into two or more physically and/or logically divided drivers, and such drivers may be disposed on one side of the display panel 110 and another side of the display panel 110 opposite the one side. As described above, the gate driver 120 may be disposed around the display panel 110 in various shapes according to embodiments.

The data driver 130 is connected to the sub-pixels SP arranged in a column direction through the first to n-th data lines DL1 to DLn. The data driver 130 receives image data DATA and a data control signal DCS from the controller 150. The data driver 130 may operate in response to the data control signal DCS. In some embodiments, the data control signal DCS may include a source start pulse, a source shift clock, a source output enable signal, and/or the like.

The data driver 130 may apply data signals, having grayscale voltages corresponding to the image data DATA, to the first to n-th data lines DL1 to DLn using voltages from the voltage generator 140. When the gate signal is applied to each of the first to m-th gate lines GL1 to GLm, the data signals corresponding to the image data DATA may be applied to the first to n-th data lines DL1 to DLn. Accordingly, the corresponding sub-pixels SP may generate light corresponding to the data signals. Accordingly, an image is displayed on the display panel 110.

In some embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device 100. For example, the voltage generator 140 may be configured to generate the plurality of voltages by receiving an input voltage from an outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than that of the first power voltage VDD (e.g., a relatively low voltage level or a low voltage). In some other embodiments, the first power voltage VDD or the second power voltage VSS may be provided by an external device of the display device 100.

In addition, the voltage generator 140 may generate various voltages. For example, the voltage generator 140 may generate an initialization voltage applied to the sub-pixels SP. For example, during a sensing operation for sensing electrical characteristics of transistors and/or light emitting elements of the sub-pixels SP, a predetermined reference voltage may be applied to the first to n-th data lines DL1 to DLn, and the voltage generator 140 may generate such a reference voltage.

The controller 150 may control overall operations of the display device 100. The controller 150 may receive input image data IMG and a control signal CTRL for controlling display of the input image data IMG from the outside. The controller 150 may provide the gate control signal GCS, the data control signal DCS, and the voltage control signal VCS in response to the control signal CTRL.

The controller 150 may convert the input image data IMG so that the input image data IMG is suitable for the display device 100 or the display panel 110 and output the image data DATA. In some embodiments, the controller 150 may output the image data DATA by aligning the input image data IMG so that the input image data IMG is suitable for the sub-pixels SP of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally divided components in one driver integrated circuit DIC. In some other embodiments, at least one of the data driver 130, the voltage generator 140, and the controller 150 may be provided as a component distinguished from (e.g., separate from or not integrated with) the driver integrated circuit DIC.

The display device 100 may include at least one temperature sensor 160. The temperature sensor 160 may be configured to sense a temperature around the temperature sensor 160 and generate temperature data TEP indicating the sensed temperature. In some embodiments, the temperature sensor 160 may be disposed adjacent to the display panel 110 and/or the driver integrated circuit DIC.

The controller 150 may control various operations of the display device 100 in response to the temperature data TEP. In some embodiments, the controller 150 may adjust a luminance of the image output from the display panel 110 in response to the temperature data TEP. For example, the controller 150 may control the data signals and the first and second power voltages VDD and VSS by controlling components such as the data driver 130 and/or the voltage generator 140.

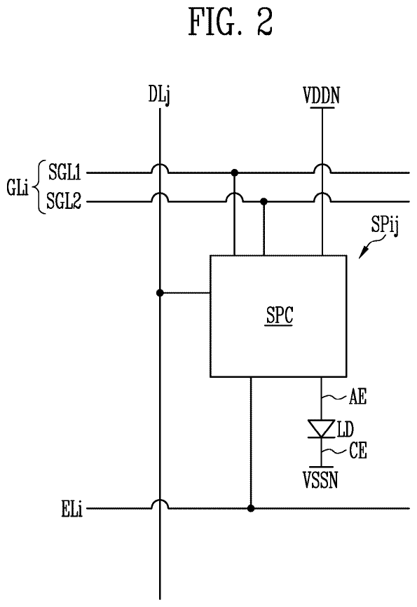

FIG. 2 is a block diagram illustrating one of the sub-pixels of FIG. 1 according to some embodiments of the present disclosure. In FIG. 2, among the sub-pixels SP of FIG. 1, a sub-pixel SPij arranged in an i-th row (i is an integer greater than or equal to 1 and less than or equal to m) and a j-th column (j is an integer greater than or equal to 1 and less than or equal to n) is shown as an example.

Referring to FIG. 2, the sub-pixel SPij may include a sub-pixel circuit SPC and a light emitting element LD.

The light emitting element LD is connected between a first power voltage node VDDN and a second power voltage node VSSN. For example, the first power voltage node VDDN may be a node that transfers the first power voltage VDD of FIG. 1, and the second power voltage node VSSN is a node that transfers the second power voltage VSS of FIG. 1.

An anode electrode AE of the light emitting element LD may be connected to the first power voltage node VDDN through the sub-pixel circuit SPC, and a cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an i-th gate line GLi among the first to m-th gate lines GL1 to GLm of FIG. 1, an i-th emission control line ELi among the first to m-th emission control lines EL1 to ELm of FIG. 1, and a j-th data line DLj among the first to n-th data lines DL1 to DLn of FIG. 1. The sub-pixel circuit SPC may be configured to control the light emitting element LD according to signals received through such signal lines.

The sub-pixel circuit SPC may operate in response to a gate signal received through the i-th gate line GLi. The i-th gate line GLi may include one or more sub-gate lines. In some embodiments, as shown in FIG. 2, the i-th gate line GLi may include first and second sub-gate lines SGL1 and SGL2. The sub-pixel circuit SPC may operate in response to gate signals received through the first and second sub-gate lines SGL1 and SGL2. As described above, when the i-th gate line GLi includes two or more sub-gate lines, the sub-pixel circuit SPC may operate in response to gate signals received through the corresponding sub-gate lines.

The sub-pixel circuit SPC may operate in response to an emission control signal received through the i-th emission control line ELi. In some embodiments, the i-th emission control line ELi may include one or more sub-emission control lines. When the i-th emission control line ELi includes two or more sub-emission control lines, the sub-pixel circuit SPC may operate in response to emission control signals received through the corresponding sub-emission control lines.

The sub-pixel circuit SPC may receive a data signal through the j-th data line DLj. The sub-pixel circuit SPC may store a voltage corresponding to the data signal in response to at least one of the gate signals received through the first and second sub-gate lines SGL1 and SGL2. The sub-pixel circuit SPC may adjust a current flowing from the first power voltage node VDDN to the second power voltage node VSSN through the light emitting element LD according to the stored voltage, in response to the emission control signal received through the i-th emission control line ELi. Accordingly, the light emitting element LD may generate light of a luminance corresponding to the data signal.

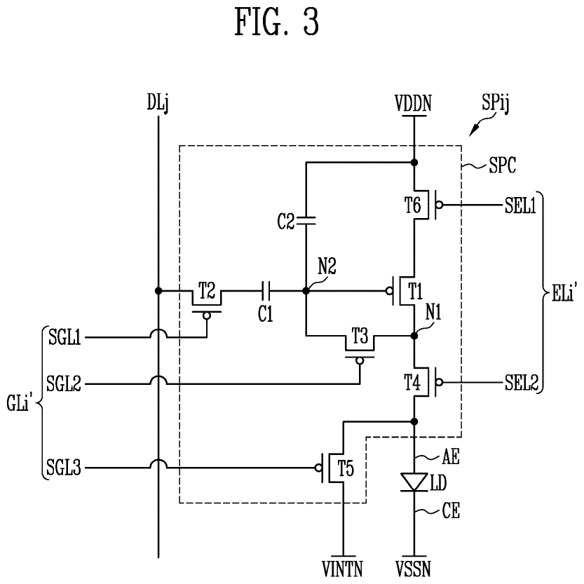

FIG. 3 is a circuit diagram illustrating the sub-pixel of FIG. 2 according to some embodiments of the present disclosure.

Referring to FIG. 3, the sub-pixel SPij may include a sub-pixel circuit SPC and a light emitting element LD.

The sub-pixel circuit SPC may be connected to an i-th gate line GLi′, an i-th emission control line ELi′, and the j-th data line DLj. Compared to the i-th gate line GLi of FIG. 2, the i-th gate line GLi′ may further include a third sub-gate line SGL3. Compared to the i-th emission control line ELi of FIG. 2, the i-th emission control line ELi′ may include a first sub-emission control line SEL1 and a second sub-emission control line SEL2.

The sub-pixel circuit SPC may include first to sixth transistors T1 to T6, and first and second capacitors C1 and C2.

The first transistor T1 may be connected between a first power voltage node VDDN and a first node N1. A gate of the first transistor T1 may be connected to a second node N2, and thus, the first transistor T1 may be turned on according to a voltage level of the second node N2. The first transistor T1 may be referred to as a driving transistor.

The second transistor T2 may be connected between the j-th data line DLj and the second node N2. A gate of the second transistor T2 may be connected to the first sub-gate line SGL1, and thus, the second transistor T2 may be turned on in response to a gate signal of the first sub-gate line SGL1. The second transistor T2 may be referred to as a switching transistor.

The third transistor T3 may be connected between the first node N1 and the second node N2. A gate of the third transistor T3 may be connected to the second sub-gate line SGL2, and thus, the third transistor T3 may be turned on in response to a gate signal of the second sub-gate line SGL2.

The fourth transistor T4 may be connected between the first node N1 and the anode electrode AE of the light emitting element LD. A gate of the fourth transistor T4 may be connected to the second sub-emission control line SEL2, and thus, the fourth transistor T4 may be turned on in response to an emission control signal of the second sub-emission control line SEL2.

The fifth transistor T5 may be connected between the anode electrode AE of the light emitting element LD and an initialization voltage node VINTN. The initialization voltage node VINTN may be configured to transfer an initialization voltage. In some embodiments, the initialization voltage may be provided by voltage generator 140 of FIG. 1. In some other embodiments, the initialization voltage may be provided by an external device of the display device 100. A gate of the fifth transistor T5 may be connected to the third sub-gate line SGL3, and thus, the fifth transistor T5 may be turned on in response to a gate signal of the third sub-gate line SGL3.

The sixth transistor T6 may be connected between the first power voltage node VDDN and the first transistor T1. A gate of the sixth transistor T6 may be connected to the first sub-emission control line SEL1, and thus, the sixth transistor T6 may be turned on in response to an emission control signal of the first sub-emission control line SEL1.

The first capacitor C1 may be connected between the second transistor T2 and the second node N2. The second capacitor C2 may be connected between the first power voltage node VDDN and the second node N2.

As described above, the sub-pixel circuit SPC may include the first to sixth transistors T1 to T6, and the first and second capacitors C1 and C2. However, embodiments are not limited thereto. The sub-pixel circuit SPC may be implemented as any of various types of circuits including a plurality of transistors and one or more capacitors. For example, the sub-pixel circuit SPC may include two transistors and one capacitor. According to embodiments of the sub-pixel circuit SPC, the number of sub-gate lines included in the i-th gate line GLi′ and the number of sub-emission control lines included in the i-th emission control line ELi′ may be variable (e.g., may vary).

The first to sixth transistors T1 to T6 may be P-type transistors. Each of the first to sixth transistors T1 to T6 may be a metal oxide silicon field effect transistor (MOSFET). However, embodiments are not limited thereto. For example, at least one of the first to sixth transistors T1 to T6 may be an N-type transistor.

In some embodiments, the first to sixth transistors T1 to T6 may include an amorphous silicon semiconductor, a monocrystalline silicon semiconductor, a polycrystalline silicon semiconductor, an oxide semiconductor, and/or the like.

The light emitting element LD may include the anode electrode AE, the cathode electrode CE, and a light emitting layer. The light emitting layer may be disposed between the anode electrode AE and the cathode electrode CE. After the data signal transferred through the j-th data line DLj is reflected in a voltage of the second node N2, when the emission control signals of the first and second sub-emission control lines SEL1 and SEL2 are enabled to a low level, the fourth and sixth transistors T4 and T6 may be turned on. In addition, the first transistor T1 may be turned on according to the voltage of the second node N2, and thus, a current may flow from the first power voltage node VDDN to the second power voltage node VSSN. The light emitting element LD may emit light according to an amount of the flowing current.

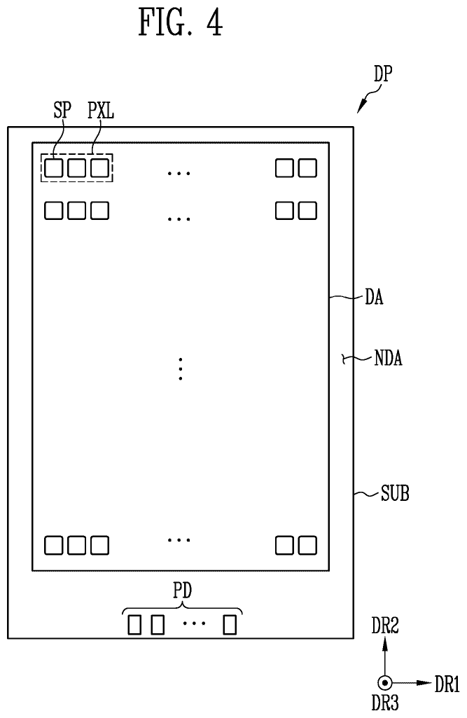

FIG. 4 is a plan view illustrating a display panel of FIG. 1 according to some embodiments of the present disclosure.

Referring to FIG. 4, some embodiments DP of the display panel 110 of FIG. 1 may include a display area DA and a non-display area NDA. The display panel DP may display an image through the display area DA. The non-display area NDA is disposed around the display area DA.

The display panel DP may include a substrate SUB, the sub-pixels SP, and pads PD.

When the display panel DP is used as a display screen of a head-mounted display (HMD), a virtual reality (VR) device, a mixed reality (MR) device, an augmented reality (AR) device, or the like, the display panel DP may be positioned very close to a user's eyes. In this case, sub-pixels SP of a relatively high integration degree may be used. In some embodiments, the display panel DP may have a relatively high resolution (e.g., pixel density). In order to increase an integration degree of the sub-pixels SP, the substrate SUB may be provided as a silicon substrate. The sub-pixels SP and/or the display panel DP may be formed on the substrate SUB, which may be the silicon substrate. The display device 100 (see, e.g., FIG. 1) including the display panel DP formed on the substrate SUB, which is the silicon substrate, may be referred to as an OLED on silicon (OLEDoS) display device.

The sub-pixels SP may be disposed in the display area DA on the substrate SUB. The sub-pixels SP may be arranged in a matrix shape along a first direction DR1 and a second direction DR2 crossing the first direction DR1. However, embodiments are not limited thereto. For example, the sub-pixels SP may be arranged in a zigzag shape along the first direction DR1 and the second direction DR2. For example, the sub-pixels SP may be arranged in a PENTILE® (Trademark of Samsung Display Co., Ltd.) shape. For example, the sub-pixels SP may be arranged in a RGBG matrix structure. The first direction DR1 may be a row direction, and the second direction DR2 may be a column direction.

Two or more sub-pixels among the plurality of sub-pixels SP may configure one pixel PXL.

A component for controlling the sub-pixels SP may be disposed in the non-display area NDA on the substrate SUB. For example, lines connected to the sub-pixels SP, such as the first to m-th gate lines GL1 to GLm and the first to n-th data lines DL1 to DLn of FIG. 1, may be disposed in the non-display area NDA.

At least one of the gate driver 120, the data driver 130, the voltage generator 140, the controller 150, and the temperature sensor 160 of FIG. 1 may be integrated in the non-display area NDA of the display panel DP. In some embodiments, the gate driver 120 of FIG. 1 may be mounted on the display panel DP and may be disposed in the non-display area NDA. In some other embodiments, the gate driver 120 may be implemented as an integrated circuit separated from the display panel DP. In some embodiments, the temperature sensor 160 may be disposed in the non-display area NDA to sense a temperature of the display panel DP.

The pads PD may be disposed in the non-display area NDA on the substrate SUB. The pads PD may be electrically connected to the sub-pixels SP through lines. For example, the pads PD may be connected to the sub-pixels SP through the first to n-th data lines DL1 to DLn.

The pads PD may interface the display panel DP to other components of the display device 100 (see, e.g., FIG. 1). In some embodiments, voltages and signals for an operation of components included in the display panel DP may be provided from the driver integrated circuit DIC of FIG. 1 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. For example, when the gate driver 120 is mounted on the display panel DP, the gate control signal GCS may be transmitted from the driver integrated circuit DIC to the gate driver 120 through the pads PD.

In some embodiments, a circuit board may be electrically connected to the pads PD using a conductive adhesive member, such as an anisotropic conductive film. In some embodiments, the circuit board may be a flexible circuit board (FPCB) or a flexible film having a flexible material. The driver integrated circuit DIC may be mounted on the circuit board to be electrically connected to the pads PD.

In some embodiments, the display area DA may have various shapes. The display area DA may have a closed loop shape including straight and/or curved sides. For example, the display area DA may have shapes such as a polygon, a circle, a semicircle, and an ellipse.

In some embodiments, the display panel DP may have a flat display surface. In some other embodiments, the display panel DP may have a display surface that is at least partially round. In some embodiments, the display panel DP may be bendable, foldable, or rollable. In these cases, the display panel DP and/or the substrate SUB may include materials having a flexible property (e.g., having suitable flexibility).

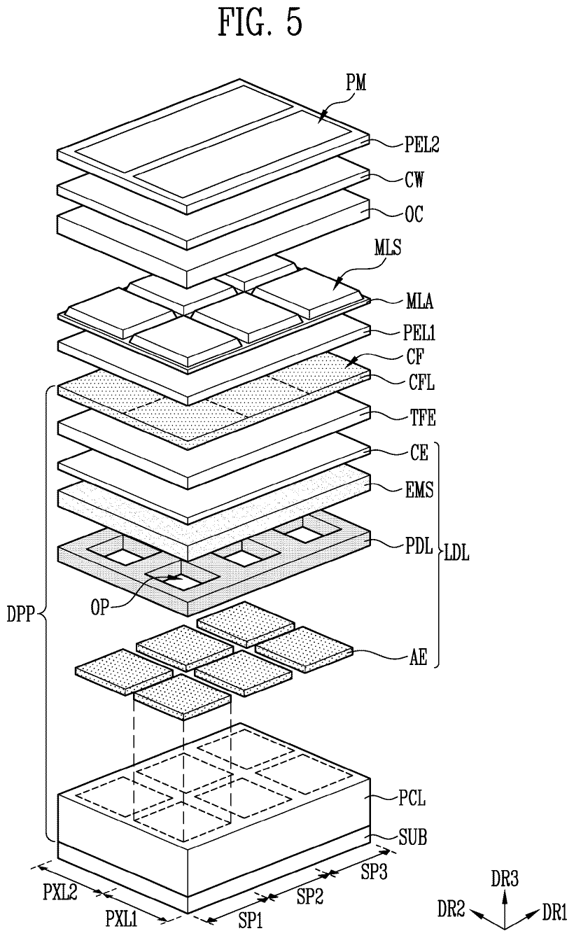

FIG. 5 is an exploded perspective view illustrating a portion of a display device according to some embodiments of the present disclosure. In FIG. 5, for clear and concise description, a portion of the display panel DP corresponding to two pixels PXL1 and PXL2 among the pixels PXL of FIG. 4 is schematically shown. A portion of the display panel DP corresponding to the remaining pixels may be similarly configured.

Referring to FIGS. 4 and 5, each of the first and second pixels PXL1 and PXL2 may include first to third sub-pixels SP1, SP2, and SP3. However, embodiments are not limited thereto. For example, each of the first and second pixels PXL1 and PXL2 may include four sub-pixels or two sub-pixels.

In FIG. 5, the first to third sub-pixels SP1, SP2, and SP3 may have quadrangle shapes when viewed from a third direction DR3 crossing the first and second directions DR1 and DR2, and may have sizes equal or substantially equal to each other. However, embodiments are not limited thereto. The first to third sub-pixels SP1, SP2, and SP3 may be modified to have various shapes.

The display panel DP may include a substrate SUB, a display unit DPP, a first polarizing element layer PEL1, a micro lens array MLA, an overcoat layer OC, a cover window CW, and a second polarizing element layer PEL2.

In some embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, or the like. In some other embodiments, the substrate SUB may include a glass substrate. In still some other embodiments, the substrate SUB may include a polyimide (PI) substrate.

The display unit DPP may be disposed on the substrate SUB. The display unit DPP may include a pixel circuit layer PCL, a light emitting element layer LDL, an encapsulation layer TFE, and a color filter layer CFL. In addition, the display unit DPP may include the first to third sub-pixels SP1 to SP3. The first to third sub-pixels SP1 to SP3 may emit light of different colors. That is, the first to third sub-pixels SP1 to SP3 may emit light having different wavelengths, respectively.

The pixel circuit layer PCL may be disposed on the substrate SUB. The substrate SUB and/or the pixel circuit layer PCL may include insulating layers and conductive patterns disposed between the insulating layers. The conductive patterns of the pixel circuit layer PCL may function as at least a portion of circuit elements, lines, and the like. The conductive patterns may include copper, but embodiments are not limited thereto.

The circuit elements may include the sub-pixel circuit SPC (see, e.g., FIG. 2) for each of the first to third sub-pixels SP1, SP2, and SP3. The sub-pixel circuit SPC may include transistors and one or more capacitors. Each transistor may include a semiconductor portion including a source area, a drain area, and a channel area, and a gate electrode overlapping the semiconductor portion. In some embodiments, when the substrate SUB is provided as a silicon substrate, the semiconductor portion may be included in the substrate SUB, and the gate electrode may be included in the pixel circuit layer PCL as a conductive pattern of the pixel circuit layer PCL. In some embodiments, when the substrate SUB is provided as a glass substrate or a PI substrate, the semiconductor portion and the gate electrode may be included in the pixel circuit layer PCL. Each capacitor may include electrodes spaced apart from each other. For example, each capacitor may include electrodes spaced apart from each other on a plane defined by the first and second directions DR1 and DR2. For example, each capacitor may include electrodes spaced apart from each other in the third direction DR3 with an insulating layer interposed therebetween.

The lines of the pixel circuit layer PCL may include signal lines connected to each of the first to third sub-pixels SP1, SP2, and SP3, for example, a gate line, an emission control line, a data line, and the like. The lines may further include a line connected to the first power voltage node VDDN of FIG. 2. In addition, the lines may further include a line connected to the second power voltage node VSSN of FIG. 2.

The light emitting element layer LDL may include the anode electrodes AE, a pixel defining layer PDL, a light emitting structure EMS, and the cathode electrode CE.

The anode electrodes AE may be disposed on the pixel circuit layer PCL. The anode electrodes AE may contact the circuit elements of the pixel circuit layer PCL. The anode electrodes AE may include an opaque conductive material capable of reflecting light, but embodiments are not limited thereto.

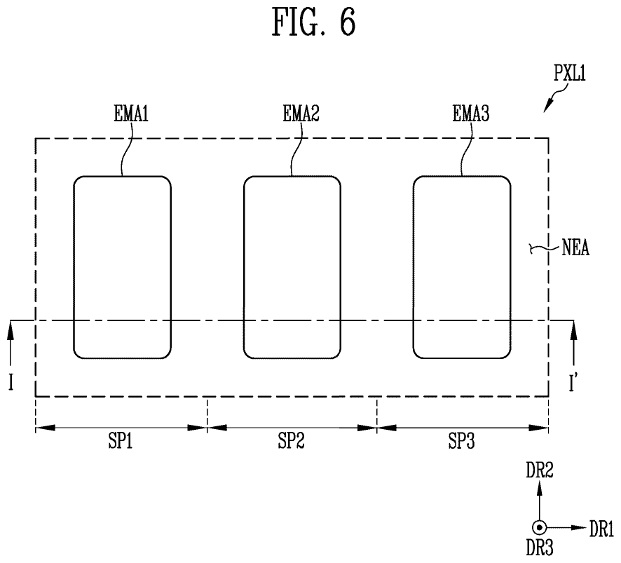

The pixel defining layer PDL may be disposed on the anode electrodes AE. The pixel defining layer PDL may include an opening OP exposing a portion of each of the anode electrodes AE. According to the opening OP of the pixel defining layer PDL, emission areas EMA1 to EMA3 (see, e.g., FIG. 6) respectively corresponding to the first to third sub-pixels SP1 to SP3 may be defined. Alternatively, it may be understood that the emission areas corresponding to the first to third sub-pixels SP1 to SP3 are defined according to the anode electrodes AE. In an area adjacent to a boundary between neighboring sub-pixels, the pixel defining layer PDL may include a separator that causes formation of a discontinuous portion (e.g., a discontinuity) in the light emitting structure EMS. For example, it may be understood that the emission areas respectively corresponding to the first to third sub-pixels SP1 to SP3 are defined according to the separators of the pixel defining layer PDL.

In some embodiments, the pixel defining layer PDL may include an inorganic material. For example, the pixel defining layer PDL may include a plurality of stacked inorganic layers. For example, the pixel defining layer PDL may include silicon oxide SiOₓ and silicon nitride SiNₓ. In some other embodiments, the pixel defining layer PDL may include an organic material. However, a material of the pixel defining layer PDL is not limited thereto.

The light emitting structure EMS may be disposed on the anode electrodes AE exposed by the opening OP of the pixel defining layer PDL. The light emitting structure EMS may include a light emitting layer configured to generate light, an electron transport layer configured to transport an electron, a hole transport layer configured to transport a hole, and/or the like.

In some embodiments, the light emitting structure EMS may fill the opening OP of the pixel defining layer PDL, and may be entirely disposed on the pixel defining layer PDL. In other words, the light emitting structure EMS may extend across the first to third sub-pixels SP1 to SP3. For example, at least a portion of layers in the light emitting structure EMS may be disconnected or bent at boundaries between the first to third sub-pixels SP1 to SP3. However, embodiments are not limited thereto. For example, portions of the light emitting structure EMS corresponding to the first to third sub-pixels SP1 to SP3 may be separated from each other, and each of the portions may be disposed in the opening OP of the pixel defining layer PDL.

The cathode electrode CE may be disposed on the light emitting structure EMS. The cathode electrode CE may extend across the first to third sub-pixels SP1 to SP3. As described above, the cathode electrode CE may be provided as a common electrode for the first to third sub-pixels SP1 to SP3.

The cathode electrode CE may be a thin metal layer having a thickness sufficient to transmit light emitted from the light emitting structure EMS. The cathode electrode CE may be formed of a metal material or a transparent conductive material to have a relatively thin (e.g., small) thickness. In some embodiments, the cathode electrode CE may include at least one of various transparent conductive materials including indium tin oxide, indium zinc oxide, indium tin zinc oxide, aluminum zinc oxide, gallium zinc oxide, zinc tin oxide, or gallium tin oxide. In some other embodiments, the cathode electrode CE may include at least one of silver (Ag), magnesium (Mg), and a mixture thereof. However, a material of the cathode electrode CE is not limited thereto.

It may be understood that any of the anode electrodes AE, a portion of the light emitting structure EMS overlapping it, and a portion of the cathode electrode CE overlapping it configure one light emitting element LD (see, e.g., FIG. 2). In other words, each of the light emitting elements LD of the first to third sub-pixels SP1 to SP3 may include one anode electrode AE, a portion of the light emitting structure EMS overlapping it, and a portion of the cathode electrode CE overlapping it. In each of the first to third sub-pixels SP1 to SP3, holes injected from the anode electrode AE and electrons injected from the cathode electrode CE may be transported into the light emitting layer of the light emitting structure EMS to form excitons, and when the excitons transits from an excited state to a ground state, light may be generated. A luminance of light may be determined according to an amount of a current flowing through the light emitting layer. According to a configuration of the light emitting layer, a wavelength range of the generated light may be determined.

The encapsulation layer TFE may be disposed on the cathode electrode CE. The encapsulation layer TFE may cover the light emitting element layer LDL and/or the pixel circuit layer PCL. The encapsulation layer TFE may be configured to prevent or substantially reduce oxygen, moisture, and/or the like from permeating to the light emitting element layer LDL. In some embodiments, the encapsulation layer TFE may include a structure in which one or more inorganic layers and one or more organic layers are alternately stacked. For example, the inorganic layer may include silicon nitride, silicon oxide, silicon oxynitride (SiOₓN_{y}), or the like. For example, the organic layer may include an organic insulating material, such as acrylic resin, epoxy resin, phenol resin, polyamide resin, polyimide resin, unsaturated polyester resin, polyphenylene ether resin, polyphenylene sulfide resin, or benzocyclobutene (BCB). However, materials of the organic layer and the inorganic layer of the encapsulation layer TFE are not limited thereto.

In order to improve an encapsulation efficiency of the encapsulation layer TFE, the encapsulation layer TFE may further include a thin film including aluminum oxide (AlOₓ). The thin film including the aluminum oxide may be positioned on an upper surface of the encapsulation layer TFE facing the color filter layer CFL and/or a lower surface of the encapsulating layer TFE facing the light emitting element layer LDL.

The thin film including the aluminum oxide may be formed through atomic layer deposition (ALD) method. However, embodiments are not limited thereto. The encapsulation layer TFE may further include a thin film formed of at least one of various materials suitable for improving the encapsulation efficiency.

The color filter layer CFL may be disposed between the encapsulation layer TFE and the first polarizing element layer PEL1. The color filter layer CFL may be configured to filter the light emitted from the light emitting structure EMS and selectively output light of a wavelength range or a color corresponding to each sub-pixel SP. The color filter layer CFL may include color filters CF respectively corresponding to the first to third sub-pixels SP1 to SP3, and each of the color filters CF may pass light of a wavelength range corresponding to the corresponding sub-pixel SP. For example, the color filter CF corresponding to the first sub-pixel SP1 may pass red color light, the color filter CF corresponding to the second sub-pixel SP2 may pass green color light, and the color filter CF corresponding to the third sub-pixel SP3 may pass blue color light. According to the light emitted from the light emitting structure EMS of each sub-pixel SP, at least a portion of the color filters CF may be omitted.

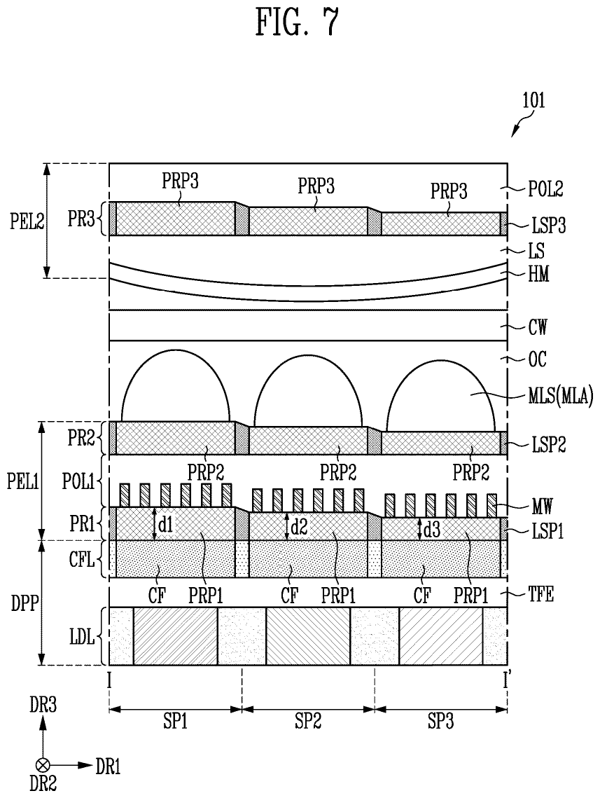

The first polarizing element layer PEL1 may be disposed on the color filter layer CFL. The first polarizing element layer PEL1 may include polarizing elements and may convert a polarization state of light emitted by each of the first to third sub-pixels SP1 to SP3. The first polarizing element layer PEL1 may include a polarizing plate (for example, a first polarizing plate POL1, refer to FIG. 7) and phase retardation plates (for example, first phase retardation plates PRP1, refer to FIG. 7) respectively corresponding to the first to third sub-pixels SP1 to SP3. Because the corresponding phase retardation plates may have different phase differences according to a wavelength of the light emitted by the first to third sub-pixels SP1 to SP3, the corresponding phase retardation plates may convert the polarization state of the light according to the wavelength of the light respectively emitted by the first to third sub-pixels SP1 to SP3.

The micro lens array MLA may be disposed on the first polarizing element layer PEL1. The micro lens array MLA may include micro lenses MLS respectively corresponding to the first to third sub-pixels SP1 to SP3.

In some embodiments, compared to the opening OP of the pixel defining layer PDL, at least a portion of the color filters CF of the color filter layer CFL and at least a portion of the micro lenses MLS of the micro lens array MLA may be shifted in a direction parallel to the plane defined by the first and second directions DR1 and DR2. For example, in a central area of the display area DA, a center of the color filter CF and a center of the micro lens MLS may be aligned with or overlap with a center of the opening OP of the corresponding pixel defining layer PDL when viewed in the third direction DR3. For example, in the central area of the display area DA, the opening OP of the pixel defining layer PDL may completely overlap the corresponding color filter of the color filter layer CFL and the corresponding lens of the micro lens array MLA. In an area adjacent to the non-display area NDA in the display area DA, the center of the color filter CF and the center of the micro lens MLS may be shifted in a plane direction from the center of the opening OP of the corresponding pixel defining layer PDL when viewed in the third direction DR3. For example, in the area adjacent to the non-display area NDA in the display area DA, the opening OP of the pixel defining layer PDL may be partially overlap of the corresponding color filter CF of the color filter layer CFL and the corresponding micro lens MLS of the micro lens array MLA. Accordingly, at a center of the display area DA, the light emitted from the light emitting structure EMS may be efficiently output in a normal direction of a display surface. At an outskirt of the display area DA, the light emitted from the light emitting structure EMS may be efficiently output in a direction inclined by a set (e.g., preset or predetermined) angle with respect to the normal direction of the display surface.

The overcoat layer OC may be disposed on the micro lens array MLA. The overcoat layer OC may cover the micro lens array MLA, the first polarizing element layer PEL1, the color filter layer CFL, the encapsulation layer TFE, the light emitting structure EMS, and/or the pixel circuit layer PCL. The overcoat layer OC may include various materials suitable for protecting layers thereunder from a foreign substance such as dust or moisture. For example, the overcoat layer OC may include at least one of an inorganic insulating layer and an organic insulating layer. For example, the overcoat layer OC may include epoxy, but embodiments are not limited thereto. The overcoat layer OC may have a refractive index lower than that of the micro lens array MLA.

The cover window CW may be disposed on the overcoat layer OC. The cover window CW is configured to protect layers thereunder. The cover window CW may have a refractive index higher than that of the overcoat layer OC. The cover window CW may include glass, but embodiments are not limited thereto. For example, the cover window CW may be an encapsulation glass configured to protect components disposed thereunder. In some other embodiments, the cover window CW may be omitted.

The second polarizing element layer PEL2 may be disposed on the color filter layer CFL. The second polarizing element layer PEL2 may include polarizing members PM respectively overlapping the first pixel PXL1 and the second pixel PXL2.

The second polarizing element layer PEL2 may include polarizing elements and may convert a polarization state of the light emitted by each of the first to third sub-pixels SP1 to SP3. In addition, the second polarizing element layer PEL2 may include a pancake lens. The pancake lens is a lens that uses folded optics and means a lens structure in which a plurality of lenses and polarizing elements overlap.

FIG. 6 is a plan view illustrating one of the pixels of FIG. 5 according to some embodiments of the present disclosure. In FIG. 6, the first pixel PXL1 among the first and second pixels PXL1 and PXL2 of FIG. 5 is schematically shown for clear and concise description. The remaining pixels may be configured similarly to the first pixel PXL1.

Referring to FIGS. 5 and 6, the first pixel PXL1 may include the first to third sub-pixels SP1 to SP3 arranged in the first direction DR1.

The first sub-pixel SP1 may include a first emission area EMA1 and a non-emission area NEA around (e.g., surrounding) the first emission area EMA1. The second sub-pixel SP2 may include a second emission area EMA2 and a non-emission area NEA around the second emission area EMA2. The third sub-pixel SP3 may include a third emission area EMA3 and a non-emission area NEA around the third emission area EMA3.

The first emission area EMA1 may be an area where light is emitted from a portion of the light emitting structure EMS (see, e.g., FIG. 5) corresponding to the first sub-pixel SP1. The second emission area EMA2 may be an area where light is emitted from a portion of the light emitting structure EMS corresponding to the second sub-pixel SP2. The third emission area EMA3 may be an area where light is emitted from a portion of the light emitting structure EMS corresponding to the third sub-pixel SP3.

FIG. 7 is a schematic cross-sectional view taken along the line I-I′ of FIG. 6 according to some embodiments of the present disclosure. In FIG. 7, the display unit DPP, the first polarizing element layer PEL1, the micro lens array MLA, the overcoat layer OC, the cover window CW, and the second polarizing element layer PEL2 of FIG. 5 are schematically shown for a clear and concise description.

Referring to FIG. 7, the display unit DPP may include the first to third sub-pixels SP1 to SP3. The first to third sub-pixels SP1 to SP3 may respectively emit light having different wavelengths. For example, the first sub-pixel SP1 may emit light of a red color, the second sub-pixel SP2 may emit light of a green color, and the third sub-pixel SP3 may emit light of a blue color. Because a wavelength of the light of the red color is the longest of the three and a wavelength of the light of the blue color is the shortest of the three, the wavelength of the light emitted by the first sub-pixel SP1 may be longer than the wavelength of the light emitted by the second and third sub-pixels SP2 and SP3, and the wavelength of the light emitted by the second sub-pixel SP2 may be longer than the wavelength of the light emitted by the third sub-pixel SP3. However, embodiments are not limited thereto.

The first polarizing element layer PEL1 may be disposed on the display unit DPP. The first polarizing element layer PEL1 may include a first phase retardation unit PR1, a first polarizing plate POL1, and a second phase retardation unit PR2.

The first phase retardation unit PR1 may be disposed on the display unit DPP. The first phase retardation unit PR1 may include first phase retardation plates PRP1 that converts a polarization state of light. For example, each of the first phase retardation plates PRP1 may be a ¼ phase retardation plate. That is, a polarization state of light passing through the first phase retardation plates PRP1 may be converted from linear polarization to circular polarization, or may be converted from circular polarization to linear polarization. Each of the first phase retardation plates PRP1 may include liquid crystal molecules. The liquid crystal molecules may be oriented in a preset direction.

The first phase retardation plates PRP1 may overlap the first to third sub-pixels SP1 to SP3, respectively, and may be spaced apart from each other. The first phase retardation plates PRP1 respectively corresponding to the first to third sub-pixels SP1 to SP3 may respectively have a phase difference corresponding to the wavelength of the light emitted by the first to third sub-pixels SP1 to SP3. Accordingly, the first phase retardation plates PRP1 respectively corresponding to the first to third sub-pixels SP1 to SP3 may have different phase differences.

Specifically, because each of the first phase retardation plates PRP1 may be a ¼ phase retardation plate, the phase difference may be λ/4. Accordingly, the respective first phase retardation plates PRP1 may have different phase differences according to a wavelength of light passing through the respective first phase retardation plates PRP1. For example, the phase difference of the first phase retardation plate PRP1 overlapping the first sub-pixel SP1 may be (center wavelength of the light of the red color/4), the phase difference of the first phase retardation plate PRP1 overlapping the second sub-pixel SP2 may be (center wavelength of the light of the green color/4), and the phase difference of the first phase retardation plate PRP1 overlapping the third sub-pixel SP3 may be (center wavelength of the light of the blue color)/4. Accordingly, the phase difference of the first phase retardation plate PRP1 overlapping the first sub-pixel SP1 may be the greatest, and the phase difference of the first phase retardation plate PRP1 overlapping the third sub-pixel SP3 may be the least.

In addition, the respective first phase retardation plates PRP1 may have different thicknesses according to a wavelength of light emitted by an overlapping sub-pixel among the first to third sub-pixels SP1 to SP3. The phase difference of each of the first phase retardation plates PRP1 may be calculated through the following formula.

Γ=2π×Δn|nₑ−nₒ|×d/λ Formula

(where, Γ: a phase difference, nₑ: a refractive index of a horizontal component, nₒ: a refractive index of a vertical component, Δn: a difference between a refractive index of a vertical component and a refractive index of a horizontal component, d: a thickness, λ: a wavelength)

That is, according to the above formula, the thickness d of the first phase retardation plate PRP1 may increase as the phase difference Γ of each of the first phase retardation plates PRP1 increases and the wavelength λ of the light passing through each of the first phase retardation plates PRP1 increases.

Accordingly, because the first phase retardation plate PRP1 overlapping the first sub-pixel SP1 has the greatest phase difference and the wavelength of the light passing through the first phase retardation plate PRP1 is the greatest, a thickness d1 of the first phase retardation plate PRP1 overlapping the first sub-pixel SP1 may be the greatest. In addition, because the first phase retardation plate PRP1 overlapping the third sub-pixel SP3 has the least phase difference and the wavelength of the light passing through the first phase retardation plate PRP1 is the least, a thickness d3 of the first phase retardation plate PRP1 overlapping the third sub-pixel SP3 may be the least. That is, the first phase retardation plate PRP1 overlapping the first sub-pixel SP1 may have the thickness d1 greater than that of the first phase retardation plates PRP1 respectively overlapping the second and third sub-pixels SP2 and SP3, and the first phase retardation plate PRP1 overlapping the second sub-pixel SP2 may have a thickness d2 greater than that of the first phase retardation plate PRP1 overlapping the third sub-pixel SP3.

By controlling the thickness of each of the first phase retardation plates PRP1, the respective first phase retardation plates PRP1 may have different phase differences according to an overlapping sub-pixel. Accordingly, the light having different wavelengths emitted from the first to third sub-pixels SP1 to SP3 may be converted from linear polarization, which is not elliptical polarization, to complete circular polarization, and from circular polarization to complete linear polarization, while respectively passing through the first phase retardation plates PRP1.

In addition, the first phase retardation unit PR1 may include a first light blocking pattern LSP1 surrounding the first phase retardation plates PRP1. The first light blocking pattern LSP1 may absorb light incident on the first light blocking pattern LSP1 to prevent or substantially reduce color mixing.

The first polarizing plate POL1 may be disposed on the first phase retardation unit PR1. The first polarizing plate POL1 may be a linear polarizing plate. For example, the first polarizing plate POL1 may be a wire grid polarizing plate. That is, the first polarizing plate POL1 may have a structure in which a metal wire MW is disposed in the first direction DR1. The first polarizing plate POL1 may transmit a P-polarization component of light parallel to the first direction DR1 which is an arrangement direction of the metal wire MW among incident light, and reflect an S-polarization component of light perpendicular to the first direction DR1 which is the arrangement direction of the metal wire MW.

The second phase retardation unit PR2 may be disposed on the first polarizing plate POL1. The second phase retardation unit PR2 may have the same structure as the first phase retardation unit PR1.

Specifically, the second phase retardation unit PR2 may include second phase retardation plates PRP2 that convert a polarization state of light. For example, each of the second phase retardation plates PRP2 may be a ¼ phase retardation plate. Each of the second phase retardation plates PRP2 may include liquid crystal molecules. The liquid crystal molecules may be oriented in a preset direction.

The second phase retardation plates PRP2 may overlap the first to third sub-pixels SP1 to SP3, respectively, and may be spaced apart from each other. The first phase retardation plates PRP1 and the second phase retardation plates PRP2 respectively overlapping the first to third sub-pixels SP1 to SP3 may overlap (e.g., overlap with) each other. That is, the first phase retardation plate PRP1 and the second phase retardation plate PRP2 overlapping the first sub-pixel SP1 may overlap each other, the first phase retardation plate PRP1 and the second phase retardation plate PRP2 overlapping the second sub-pixel SP2 may overlap each other, and the first phase retardation plate PRP1 and the second phase retardation plate PRP2 overlapping the third sub-pixel SP3 may overlap each other.

The second phase retardation plates PRP2 respectively corresponding to the first to third sub-pixels SP1 to SP3 may have a phase difference corresponding to the wavelength of the light emitted by the first to third sub-pixels SP1 to SP3. Accordingly, the second phase retardation plates PRP2 respectively corresponding to the first to third sub-pixels SP1 to SP3 may have different phase differences. Similarly to the first phase retardation plates PRP1, the phase difference of the second phase retardation plate PRP2 overlapping the first sub-pixel SP1 may be the greatest, and the phase difference of the second phase retardation plate PRP2 overlapping the third sub-pixel SP3 may be the least.

In addition, the respective second phase retardation plates PRP2 may have different thicknesses according to a wavelength of light emitted by an overlapping sub-pixel among the first to third sub-pixels SP1 to SP3. Similarly to the first phase retardation plates PRP1, as the phase difference of each of the second phase retardation plates PRP2 increases and the wavelength of light passing through each of the second phase retardation plates PRP2 increases, the thickness of the second phase retardation plates PRP2 may increase. Accordingly, the second phase retardation plate PRP2 overlapping the first sub-pixel SP1 may have a thickness greater than that of the second phase retardation plates PRP2 respectively overlapping the second and third sub-pixels SP2 and SP3, and the second phase retardation plate PRP2 overlapping the second sub-pixel SP2 may have a thickness greater than that of the second phase retardation plate PRP2 overlapping the third sub-pixel SP3.

By controlling the thickness of each of the second phase retardation plates PRP2, the respective second phase retardation plates PRP2 may have different phase differences according to an overlapping sub-pixel. Accordingly, the light having different wavelengths emitted from the first to third sub-pixels SP1 to SP3 may be converted from linear polarization, which is not elliptical polarization, to complete circular polarization, and from circular polarization to complete linear polarization, while respectively passing through the second phase retardation plates PRP2.

In addition, the second phase retardation unit PR2 may include a second light blocking pattern LSP2 surrounding the second phase retardation plates PRP2. The second light blocking pattern LSP2 may absorb light incident on the second light blocking pattern LSP2 to prevent or substantially reduce color mixing.

The first polarizing plate POL1 may transmit a P-polarization component of light parallel to the first direction DR1 which is the arrangement direction of the metal wire MW among light emitted from the display unit DPP, and may reflect an S-polarization component of light perpendicular to the first direction DR1 which is the arrangement direction of the metal wire MW. The S-polarization component reflected by the first polarizing plate POL1 may pass through the first phase retardation unit PR1, may be converted into circularly polarized light, and may be incident on the display unit DPP. The light converted into circularly polarized light may be reflected again by metal layers (for example, the anode electrode AE and the cathode electrode CE of FIG. 5) of the display unit DPP, may pass through the first phase retardation unit PR1, and may be converted into a P-polarization component. The P-polarization component may pass through the first polarizing plate POL1, may pass through the second phase retardation unit PR2, and may be converted into circularly polarized light.

The micro lens array MLA may be disposed on the first polarizing element layer PEL1. The micro lens array MLA may include micro lenses MLS respectively overlapping the first to third sub-pixels SP1 to SP3. Each of the micro lenses MLS may improve light emission efficiency by outputting light emitted from the light emitting structure EMS to an intended path. The micro lens array MLA may have a relatively high refractive index. For example, the micro lens array MLA may have a refractive index higher than that of the overcoat layer OC. In some embodiments, the micro lenses MLS may include an organic material. In some embodiments, the micro lenses MLS may include an acrylic material. However, a material of the micro lenses MLS is not limited thereto.

The overcoat layer OC may cover the micro lens array MLA on the micro lens array MLA. The cover window CW may be disposed on the overcoat layer OC.

The second polarizing element layer PEL2 may be disposed on the cover window CW. The second polarizing element layer PEL2 may include a pancake lens. The second polarizing element layer PEL2 may entirely overlap the first to third sub-pixels SP1 to SP3. Each of the polarizing members PM (see, e.g., FIG. 5) included in the second polarizing element layer PEL2 may overlap one pixel PXL1 or PXL2 (see, e.g., FIG. 5) including the first to third sub-pixels SP1 to SP3. That is, one polarizing member PM may be disposed per one pixel PXL1 or PXL2.

The second polarizing element layer PEL2 may include a half mirror HM, a lens LS, a third phase retardation unit PR3, and a second polarizing plate POL2.

The half mirror HM may be disposed on the cover window CW. The half mirror HM may transmit light incident in the third direction DR3 (for example, light incident from a lower portion of the half mirror HM) and reflect light incident in a direction (for example, light incident from an upper portion of the half mirror HM) opposite to the third direction DR3.

The third phase retardation unit PR3 may be disposed on the half mirror HM. The third phase retardation unit PR3 may have the same structure as the first and second phase retardation units PR1 and PR2. Therefore, the third phase retardation unit PR3 may include third phase retardation plates PRP3 that convert a polarization state of light. Each of the third phase retardation plates PRP3 may be a ¼ phase retardation plate. The third phase retardation plates PRP3 respectively corresponding to the first to third sub-pixels SP1 to SP3 may have different phase differences. The respective third phase retardation plates PRP3 may have different thicknesses according to a wavelength of light emitted by an overlapping sub-pixel among the first to third sub-pixels SP1 to SP3. In addition, the third phase retardation unit PR3 may include a third light blocking pattern LSP3 surrounding the third phase retardation plates PRP3. The third light blocking pattern LSP3 may absorb light incident on the third light blocking pattern LSP3 to prevent or substantially reduce color mixing.

The second polarizing plate POL2 may be disposed on the third phase retardation unit PR3. The second polarizing plate POL2 may be a reflective polarizing plate. Therefore, the second polarizing plate POL2 may reflect a portion of incident light and transmit a portion of the incident light.

In some embodiments, the second polarizing plate POL2 may have the same structure as the first polarizing plate POL1. For example, the second polarizing plate POL2 may be a wire grid polarizing plate. That is, the second polarizing plate POL2 may have a structure in which a metal wire MW is disposed in the first direction DR1. The second polarizing plate POL2 may transmit a P-polarization component of light parallel to the first direction DR1 which is an arrangement direction of the metal wire MW among incident light, and reflect an S-polarization component of light perpendicular to the first direction DR1 which is the arrangement direction of the metal wire MW.

At least one lens LS may be disposed between the half mirror HM and the second polarizing plate POL2. The lens LS may have a structure in which a convex lens and a concave lens are combined. Through this, the lens LS may magnify an image.

In some embodiments, the lens LS may be disposed between the half mirror HM and the third phase retardation unit PR3. In some other embodiments, the lens LS may be disposed between the third phase retardation unit PR3 and the second polarizing plate POL2. In still some other embodiments, the lens LS may be disposed between the half mirror HM and the third phase retardation unit PR3 and between the third phase retardation unit PR3 and the second polarizing plate POL2, respectively. However, embodiments are not limited thereto.

The light passing through the first polarizing element layer PEL1 and converted into circularly polarized light may transmit through the half mirror HM, may pass through the third phase retardation unit PR3, and may be converted into linearly polarized light. The light converted into linearly polarized light may be reflected by the second polarizing plate POL2, may pass through the third phase retardation unit PR3 again, and may be converted into circularly polarized light. The light converted into circularly polarized light again may be reflected by the half mirror HM, may be incident on the third phase retardation unit PR3, may pass through the third phase retardation unit PR3, and may be converted into linearly polarized light again. The light converted into linearly polarized light may transmit through the second polarizing plate POL2, and may emitted to an outside of a display device 101.

In some embodiments, as phase retardation plates having different thicknesses for each sub-pixel are disposed on the display unit DPP, the phase retardation unit may respectively implement a phase difference of ¼ wavelength with respect to light of all wavelengths emitted by the sub-pixel. Accordingly, because linear polarization is converted into complete circular polarization and circular polarization is converted into complete linear polarization with respect to light of all wavelengths emitted by the sub-pixel, a ghost phenomenon for each wavelength may be improved. In addition, a luminance and a light emission efficiency of the display device 101 may be improved.

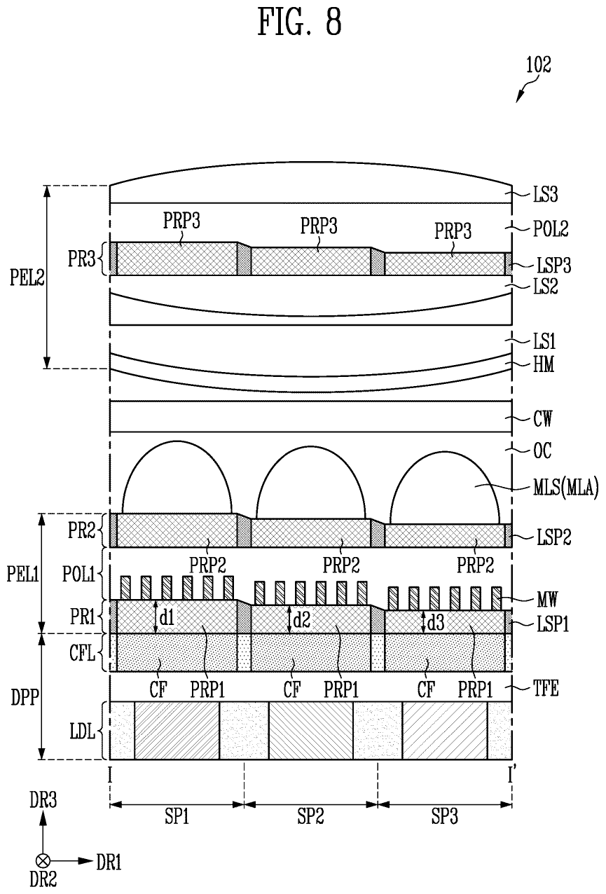

FIG. 8 is a schematic cross-sectional view according to some other embodiments of the present disclosure.

A display device 102 according to some embodiments is different from the display device 101 of FIG. 7 described above, in that the second polarizing element layer PEL2 includes first to third lenses LS1 to LS3. Therefore, a content that may overlap the content described above is briefly described or is not repeated.

Referring to FIG. 8, the second polarizing element layer PEL2 may include the half mirror HM, a first lens LS1, a second lens LS2, the third phase retardation unit PR3, the second polarizing plate POL2, and a third lens LS3.

The first lens LS1 may be disposed between the half mirror HM and the third phase retardation unit PR3. The second lens LS2 may be disposed between the first lens LS1 and the third phase retardation unit PR3. The third lens LS3 may be disposed on the second polarizing plate POL2. Each of the first to third lenses LS1 to LS3 may have a structure in which a convex lens and a concave lens are combined. Through this, the first to third lenses LS1 to LS3 may magnify an image.

Because the second polarizing element layer PEL2 includes three lenses, the image may be further magnified, and chromatic aberration of the lens may be reduced. Through this, display quality of the display device 102 may be improved. Embodiments are not limited thereto, and the second polarizing element layer PEL2 may include four or more lenses.

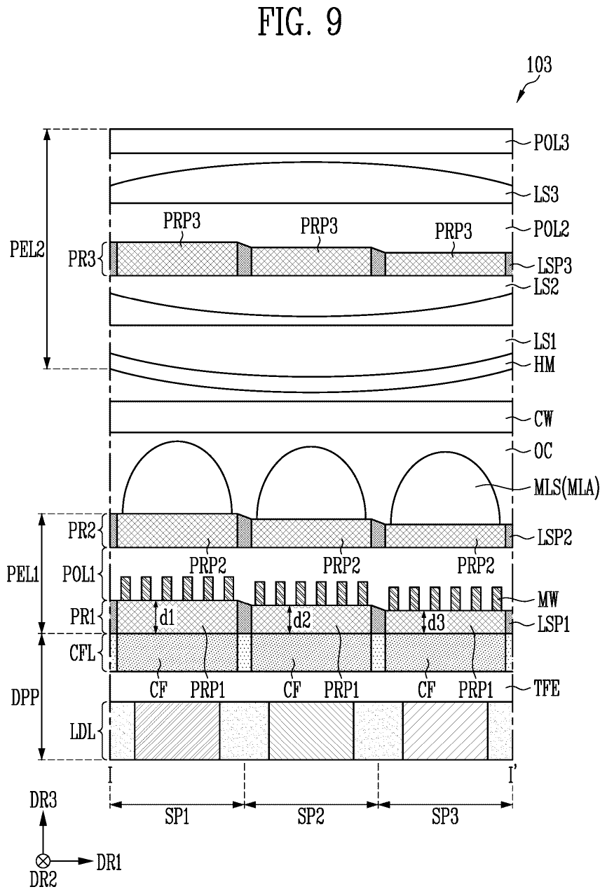

FIG. 9 is a schematic cross-sectional view according to still other embodiments of the present disclosure.

The display device 103 according to some embodiments is different from the display device 102 of FIG. 8 described above, in that the display device 103 further includes a third polarizing plate POL3. Therefore, a content that may overlap the content described above is briefly described or is not repeated.

Referring to FIG. 9, the second polarizing element layer PEL2 may include the half mirror HM, the first lens LS1, the second lens LS2, the third phase retardation unit PR3, the second polarizing plate POL2, the third lens LS3, and the third polarizing plate POL3.

The third polarizing plate POL3 may be disposed on the third lens LS3. The third polarizing plate POL3 may be an absorption-type polarizing plate. As the third polarizing plate POL3 may be disposed at the uppermost portion of the display device 103, when external light incident on the display device 103 is reflected by the second polarizing element layer PEL2, the third polarizing plate POL3 may absorb the reflected light. That is, the third polarizing plate POL3 may prevent or substantially block external light from being reflected and emitted to an outside of the display device 103. Accordingly, external light reflection of the display device 103 may be prevented or the amount or frequency of external light reflection may be substantially reduced.

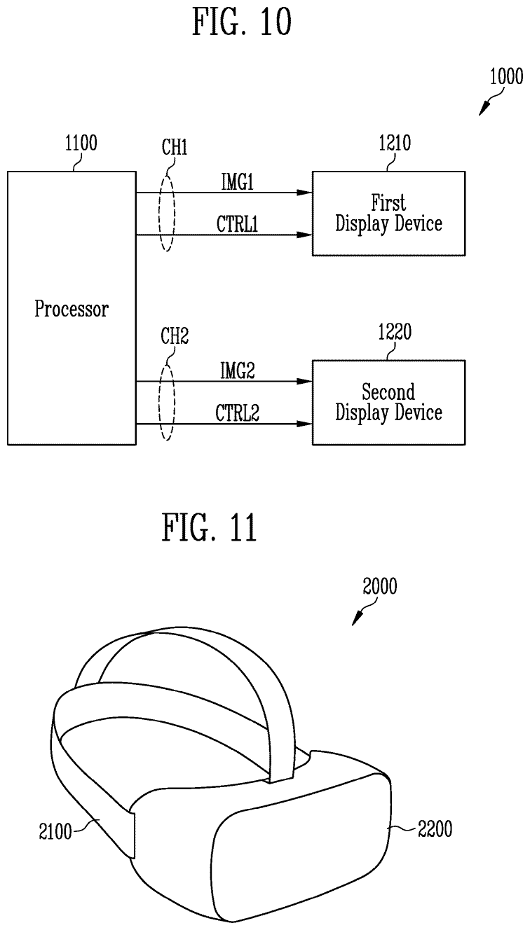

FIG. 10 is a block diagram illustrating some embodiments of a display system according to some embodiments of the present disclosure.

Referring to FIG. 10, the display system 1000 may include a processor 1100 and one or more display devices 1210 and 1220.

The processor 1100 may perform various tasks and calculations. In some embodiments, the processor 1100 may include an application processor, a graphic processor, a microprocessor, a central processing unit (CPU), and/or the like. The processor 1100 may be connected to other components of the display system 1000 through a bus system and may control the other components.

In FIG. 10, the display system 1000 includes the first and second display devices 1210 and 1220. The processor 1100 may be connected to the first display device 1210 through a first channel CH1 and may be connected to the second display device 1220 through a second channel CH2.

Through the first channel CH1, the processor 1100 may transmit first image data IMG1 and a first control signal CTRL1 to the first display device 1210. The first display device 1210 may display an image based on the first image data IMG1 and the first control signal CTRL1. The first display device 1210 may be configured similarly to the display device 100 described with reference to FIG. 1. For example, the first image data IMG1 and the first control signal CTRL1 may be provided as the input image data IMG and the control signal CTRL of FIG. 1, respectively.

Through the second channel CH2, the processor 1100 may transmit second image data IMG2 and a second control signal CTRL2 to the second display device 1220. The second display device 1220 may display an image based on the second image data IMG2 and the second control signal CTRL2. The second display device 1220 may be configured similarly to the display device 100 described with reference to FIG. 1. For example, the second image data IMG2 and the second control signal CTRL2 may be provided as the input image data IMG and the control signal CTRL of FIG. 1, respectively.

The display system 1000 may include a computing system providing an image display function, such as a portable computer, a mobile phone, a smart phone, a tablet personal computer (PC), a smart watch, a watch phone, a portable multimedia player (PMP), a navigation device, an ultra mobile personal computer (UMPC), or the like. In addition, the display system 1000 may include at least one of a head-mounted display (HMD) device, a virtual reality (VR) device, a mixed reality (MR) device, an augmented reality (AR) device, or the like.

FIG. 11 is a perspective view illustrating an application example of the display system of FIG. 10 according to some embodiments of the present disclosure.

Referring to FIG. 11, the display system 1000 of FIG. 10 may be applied to a head-mounted display device 2000. The head-mounted display device 2000 may be a wearable electronic device that may be worn on a user's head.

The head-mounted display device 2000 may include a head mount band 2100 and a display device receiving case 2200. The head mount band 2100 may be connected to the display device receiving case 2200. The head mount band 2100 may include a horizontal band and/or a vertical band for fixing the display device receiving case 2200 to the user's head. The horizontal band may be configured to surround a side portion of the user's head, and the vertical band may be configured to surround an upper portion of the user's head. However, embodiments are not limited thereto. For example, the head mount band 2100 may be implemented in a glasses frame form, a helmet form, or the like.

The display device receiving case 2200 may receive the first and second display devices 1210 and 1220 of FIG. 10. The display device receiving case 2200 may further receive the processor 1100 of FIG. 10.

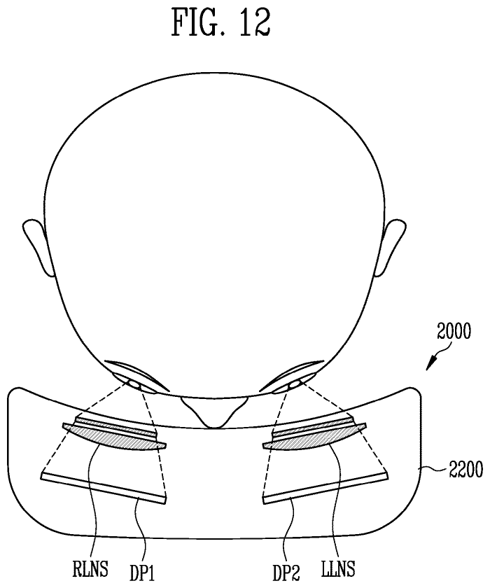

FIG. 12 is a diagram illustrating the head-mounted display device worn by a user of FIG. 11 according to some embodiments of the present disclosure.

Referring to FIG. 12, in a head-mounted display device 2000, a first display panel DP1 of the first display device 1210 and a second display panel DP2 of the second display device 1220 are disposed. The head-mounted display device 2000 may further include one or more lenses LLNS and RLNS.

Within the display device receiving case 2200, the right eye lens RLNS may be disposed between the first display panel DP1 and a user's right eye. Within the display device receiving case 2200, the left eye lens LLNS may be disposed between the second display panel DP2 and a user's left eye.

An image output from the first display panel DP1 may be displayed to the user's right eye through the right eye lens RLNS. The right eye lens RLNS may refract light from the first display panel DP1 to be directed toward the user's right eye. The right eye lens RLNS may perform an optical function for adjusting a viewing distance between the first display panel DP1 and the user's right eye.

An image output from the second display panel DP2 may be displayed to the user's left eye through the left eye lens LLNS. The left eye lens LLNS may refract light from the second display panel DP2 to be directed toward the user's left eye. The left eye lens LLNS may perform an optical function for adjusting a viewing distance between the second display panel DP2 and the user's left eye.

In some embodiments, each of the right eye lens RLNS and the left eye lens LLNS may include an optical lens having a pancake-shaped cross-section. In embodiments, each of the right eye lens RLNS and the left eye lens LLNS may include a multi-channel lens including sub-areas having different optical characteristics. In this case, each display panel may output images respectively corresponding to the sub-areas of the multi-channel lens, and the output images may pass through the respective corresponding sub-areas and may be viewed to the user.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and equivalents thereof.

What is claimed is:

1. A display device comprising:
a substrate;
a display unit on the substrate, and comprising first to third sub-pixels configured to emit light of different colors;
a first phase retardation unit on the display unit, and comprising first phase retardation plates respectively overlapping with the first to third sub-pixels and having different phase differences from each other;
a first polarizing plate on the first phase retardation unit;
a second phase retardation unit on the first polarizing plate, and comprising second phase retardation plates respectively overlapping with the first to third sub-pixels and having different phase differences from each other; and
a polarizing element layer on the second phase retardation unit, and comprising a pancake lens.

2. The display device according to claim 1, wherein each of the first and second phase retardation plates has a phase difference corresponding to a wavelength of light emitted by a corresponding overlapping sub-pixel among the first to third sub-pixels.

3. The display device according to claim 2, wherein each of the first and second phase retardation plates has thicknesses different from each other according to the wavelength of the light emitted by the corresponding overlapping sub-pixel among the first to third sub-pixels.

4. The display device according to claim 3, wherein a wavelength of the light emitted by the first sub-pixel is longer than a wavelength of the light emitted by the second and third sub-pixels, and the wavelength of the light emitted by the second sub-pixel is longer than the wavelength of the light emitted by the third sub-pixel.

5. The display device according to claim 4, wherein among the first and second phase retardation plates, phase retardation plates overlapping with the first sub-pixel have a thickness greater than that of phase retardation plates overlapping with the second and third sub-pixels.

6. The display device according to claim 5, wherein among the first and second phase retardation plates, the phase retardation plates overlapping with the second sub-pixel have a thickness greater than that of phase retardation plates overlapping with the third sub-pixel.

7. The display device according to claim 2, wherein each of the first and second phase retardation plates is a ¼ phase retardation plate.

8. The display device according to claim 7, wherein the first phase retardation plates and the second phase retardation plates respectively overlapping with the first to third sub-pixels overlap with each other, and
the first phase retardation unit and the second phase retardation unit have substantially the same structure.

9. The display device according to claim 1, wherein each of the first and second phase retardation plates comprises liquid crystal molecules.

10. The display device according to claim 1, wherein the first phase retardation unit further comprises a first light blocking pattern surrounding the first phase retardation plates, and
the second phase retardation unit further comprises a second light blocking pattern surrounding the second phase retardation plates.

11. The display device according to claim 1, wherein the polarizing element layer overlaps with the first to third sub-pixels.

12. The display device according to claim 11, wherein the polarizing element layer comprises:
a half mirror on the second phase retardation unit;
a third phase retardation unit on the half mirror;
a second polarizing plate on the third phase retardation unit; and
at least one lens between the half mirror and the second polarizing plate.

13. The display device according to claim 12, wherein the polarizing element layer comprises at least one first lens between the half mirror and the third phase retardation unit.

14. The display device according to claim 13, wherein the polarizing element layer comprises a second lens on the second polarizing plate.

15. The display device according to claim 12, wherein the third phase retardation unit has substantially the same structure as the first and second phase retardation units.

16. The display device according to claim 12, wherein the second polarizing plate has substantially the same structure as the first polarizing plate.

17. The display device according to claim 12, wherein the polarizing element layer further comprises a third polarizing plate on the second polarizing plate.

18. The display device according to claim 17, wherein the third polarizing plate is an absorption-type polarizing plate.

19. The display device according to claim 1, further comprising:
a micro lens array between the second phase retardation unit and the polarizing element layer.

20. An electronic device, comprising:
a processor to provide input image data; and
a display device to display an image based on the input image data,
a display device comprising:
a substrate;
a display unit on the substrate, and comprising first to third sub-pixels configured to emit light of different colors;
a first phase retardation unit on the display unit, and comprising first phase retardation plates respectively overlapping with the first to third sub-pixels and having different phase differences from each other;
a first polarizing plate on the first phase retardation unit;
a second phase retardation unit on the first polarizing plate, and comprising second phase retardation plates respectively overlapping with the first to third sub-pixels and having different phase differences from each other; and
a polarizing element layer on the second phase retardation unit, and comprising a pancake lens.
